(19) United States
(12) Patent Application Publication
(10) Pub. No.: US 2022/0120945 A1
(43) Pub. Date: Apr. 21, 2022

(54) FEEDBACK SENSOR FOR MEMS MIRROR

(71) Applicant: GM Global Technology Operations LLC, Detroit, MI (US)

(72) Inventors: Steven A. Del Gaizo, Ferndale, MI (US); Vincent Kuenlin, Fribourg (CH)

(21) Appl. No.: 17/072,224

(22) Filed: Oct. 16, 2020

(51) Int. Cl. G02B 5/08; G02B 5/26; B60R 1/12; B81B 3/00

(52) U.S. Cl. CPC G02B 5/08; G02B 5/26; B81B 2201/047; B81B 3/0018; B60R 1/12

(57) ABSTRACT

An optical mirror assembly includes a mirror with a reflective surface and a back surface, opposite the reflective surface. The mirror is tilted around a first axis or a second axis, perpendicular to the first axis. The optical mirror assembly also includes an inverted light emitting device (LED) of a feedback sensor arranged to emit light onto the back surface of the mirror, and four photodiodes of the feedback sensor arranged to receive reflected light resulting from the back surface of the mirror reflecting the light emitted by the inverted LED. Each of the four photodiodes is disposed in a different one of four quadrants defined by the first axis and the second axis and the inverted LED being disposed at a center of the four photodiodes.

### INTRODUCTION

The subject disclosure relates to a feedback sensor for a micro-electromechanical system (MEMS) mirror.

An optical mirror may be used to direct or deflect light in a number of applications (e.g., beamsteering in a lidar sensor, two-dimensional optical scanning). The optical mirror may be tilted as needed using a micro-electromechanical system (MEMS). The orientation of this so-called MEMS mirror may not precisely match a desired orientation that is controlled via the MEMS. That is, real-world conditions such as temperature, shock, and vibration, may prevent a given signal to the MEMS from resulting in the orientation of the optical mirror that is expected based on laboratory conditions. Accordingly, it is desirable to provide a feedback sensor for a MEMS mirror.

### SUMMARY

In one exemplary embodiment, an optical mirror assembly includes a mirror with a reflective surface and a back surface, opposite the reflective surface. The mirror is tilted around a first axis or a second axis, perpendicular to the first axis. The optical mirror assembly also includes an inverted light emitting device (LED) of a feedback sensor arranged to emit light onto the back surface of the mirror, and four photodiodes of the feedback sensor arranged to receive reflected light resulting from the back surface of the mirror reflecting the light emitted by the inverted LED. Each of the four photodiodes is disposed in a different one of four quadrants defined by the first axis and the second axis and the inverted LED being disposed at a center of the four photo diodes.

In addition to one or more of the features described herein, the optical mirror assembly also includes actuators to tilt the mirror around the first axis or the second axis based on control signals provided to the actuators.

In addition to one or more of the features described herein, each of the actuators is a micro-electro-mechanical system.

In addition to one or more of the features described herein, the optical mirror assembly also includes a controller to provide the control signals to the actuators to orient the mirror with a desired tilt angle around the first axis and a desired tilt angle around the second axis.

In addition to one or more of the features described herein, the controller obtains an indication of intensity of the reflected light received by each of the four photodiodes.

In addition to one or more of the features described herein, the controller determines actual orientation of the mirror including an actual tilt angle around the first axis and an actual tilt angle around the second axis based on the intensity of the reflected light received from the four photodiodes, the intensity of the reflected light received from all of the four photodiodes being used to determine both the actual tilt angle around the first axis and the actual tilt angle around the second axis.

In addition to one or more of the features described herein, the controller determines a correction in orientation as a difference between the actual tilt angle and the desired tilt angle around the first axis and a difference between the actual tilt angle and the desired tilt angle around the second axis.

In addition to one or more of the features described herein, the controller provides correction control signals to the actuators based on the correction in orientation to achieve the desired tilt angle around the first axis and the desired tilt angle around the second axis.

In another exemplary embodiment, a method of assembling an optical mirror assembly includes disposing a mirror with a reflective surface and a back surface, opposite the reflective surface. The mirror is tilted around a first axis or a second axis, perpendicular to the first axis. The method also includes arranging an inverted light emitting device (LED) of a feedback sensor to emit light onto the back surface of the mirror, and arranging four photodiodes of the feedback sensor to receive reflected light resulting from the back surface of the mirror reflecting the light emitted by the inverted LED. Each of the four photodiodes is disposed in a different one of four quadrants defined by the first axis and the second axis and the inverted LED being disposed in a center of the four photodiodes.

In addition to one or more of the features described herein, the method also includes arranging actuators to tilt the mirror around the first axis or the second axis based on control signals provided to the actuators.

In addition to one or more of the features described herein, the method also includes configuring a controller to provide the control signals to the actuators to orient the mirror with a desired tilt angle around the first axis and a desired tilt angle around the second axis.

In addition to one or more of the features described herein, the method also includes coupling the controller to the four photodiodes to obtain an indication of intensity of the reflected light received by each of the four photodiodes.

In addition to one or more of the features described herein, the method also includes configuring the controller to determine actual orientation of the mirror including an actual tilt angle around the first axis and an actual tilt angle around the second axis based on the intensity of the reflected light received from the four photodiodes, wherein the intensity of the reflected light received from all of the four photodiodes is used to determine both the actual tilt angle around the first axis and the actual tilt angle around the second axis.

In addition to one or more of the features described herein, the method also includes configuring the controller to determine a correction in orientation as a difference between the actual tilt angle and the desired tilt angle around the first axis and a difference between the actual tilt angle and the desired tilt angle around the second axis.

In addition to one or more of the features described herein, the method also includes configuring the controller to provide correction control signals to the actuators based on the correction in orientation to achieve the desired tilt angle around the first axis and the desired tilt angle around the second axis.

In yet another exemplary embodiment, a method of performing closed-loop control of a mirror of an optical mirror assembly includes emitting light, using an inverted light emitting device (LED), onto a back surface of a mirror with a reflective surface opposite the back surface. The mirror tilts around a first axis or a second axis that is perpendicular to the first axis. The method also includes receiving reflected light, using four photodiodes respectively disposed in different ones of four quadrants defined by the first axis and the second axis, the reflected light resulting from the back surface of the mirror reflecting the light emitted by the inverted LED, the inverted LED being disposed in a center of the four photodiodes.

In addition to one or more of the features described herein, the method also includes providing, using a controller, control signals to micro-electro-mechanical actuators to tilt the mirror to a desired tilt angle around the first axis and a desired tilt angle around the second axis according to the control signals.

In addition to one or more of the features described herein, the method also includes the controller obtaining an indication of intensity of the reflected light received by each of the four photodiodes.

In addition to one or more of the features described herein, the method also includes the controller determining a true tilt angle around the first axis using the intensity of the reflected light received by all of the four photodiodes and determining a true tilt angle around the second axis using the intensity of the reflected light received by all of the four photodiodes.

In addition to one or more of the features described herein, the method also includes the controller providing additional control signals to the actuators based on a difference between the actual tilt angle and the desired tilt angle around the first axis and a difference between the actual tilt angle and the desired tilt angle around the second axis to obtain the desired tilt angle around the first axis and the desired tilt angle around the second axis for the mirror.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings in which:

FIG. 1 is a block diagram of a vehicle that includes a feedback sensor for a MEMS mirror according to one or more embodiments;

FIG. 2 is a block diagram of aspects of an exemplary optical mirror assembly that implements closed-loop control of an orientation of the MEMS mirror according to one or more embodiments;

FIG. 3 is a cross-sectional view of relevant aspects of an exemplary optical mirror assembly that includes a feedback sensor to facilitate closed-loop control of an orientation of the MEMS mirror according to one or more embodiments;

FIG. 4 is a side view of aspects of a feedback sensor for the MEMS mirror according to one or more embodiments;

FIG. 5 is a block diagram of a feedback sensor for the MEMS mirror according to one or more embodiments; and

FIG. 6 is a process flow of a method of performing closed-loop control of the orientation of a MEMS mirror based on a feedback sensor according to one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features.

Vehicles (e.g., automobiles, trucks, construction equipment, farm equipment, automated factory equipment) increasingly employ sensors to obtain information about the vehicle and its environment. Information from the sensors facilitates semi-autonomous operation (e.g., lane departure correction, automated steering or braking) and autonomous operation of the vehicle. Exemplary sensors that are typically used to obtain information about the environment of the vehicle include cameras, radio detection and ranging (radar) systems, and light detection and ranging (lidar) systems. A lidar system of a vehicle may be among the devices that employ one or more MEMS mirrors.

Embodiments of the systems and methods detailed herein relate to a feedback sensor for a MEMS mirror. As previously noted, the true orientation (e.g., tilt angle) of a MEMS mirror may differ from the desired orientation that gave rise to a signal to the MEMS, which actuates the movement. A feedback sensor that provides the true orientation of the MEMS mirror facilitates closed-loop control to obtain the desired orientation through adjustments of the signal (e.g., current) to the MEMS, as detailed. The feedback sensor according to exemplary embodiments differs in three substantial ways from prior feedback sensors.

An inverted light emitting diode (LED), which exhibits a different illumination to MEMS mirror tilt angle characteristic as compared with a conventional LED is used. Photodiodes used as detectors in the feedback sensor are arranged differently than in conventional feedback sensors, and the calculation of the MEMS mirror tilt angle differs from the calculation used in conventional feedback sensors due to the different arrangement of photodiodes. The feedback sensor is arranged on a back side of the MEMS mirror (i.e., opposite the side used as an optical mirror). The inverted LED is used to emit light on the back side of the MEMS mirror and the photodiodes are arranged to receive reflections resulting from the emitted light.

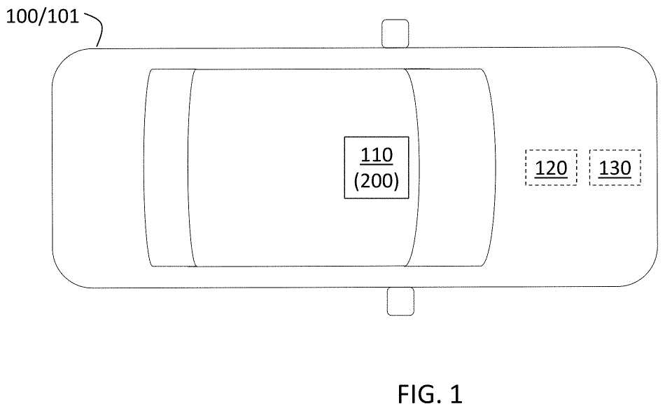

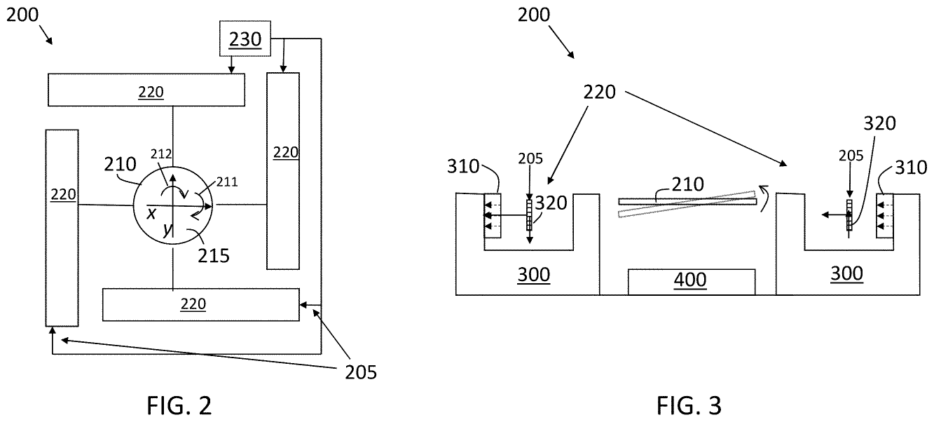

In accordance with an exemplary embodiment, FIG. 1 is a block diagram of a vehicle 100 that includes a feedback sensor 400 (FIG. 3) for a MEMS mirror 210 (FIG. 2). The exemplary vehicle 100 shown in FIG. 1 is an automobile 101. A lidar system 110 is shown on the roof of the vehicle 100. The optical mirror assembly 200 used in the lidar system 110 and, more particularly, the feedback sensor 400 used in closed-loop control of the orientation of the mirror 210 are detailed with reference to FIGS. 2-6. The vehicle 100 includes a controller 120 and may include additional sensors 130 (e.g., camera, radar system). The numbers and locations of the lidar system 110 and additional sensors 130 is not intended to be limited by the exemplary illustration in FIG. 1.

The controller 120 may obtain information from the lidar system 110 and/or additional sensors 130 to control aspects of the operation of the vehicle 100. The information may facilitate semi-autonomous or autonomous operation, for example. The controller 120 may additionally interact with the optical mirror assembly 200 and participate in the control and/or closed-loop control of the MEMS mirror 210 as further discussed. The controller 120 may include processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

FIG. 2 is a block diagram of aspects of an exemplary optical mirror assembly 200 that implements closed-loop control of an orientation of the MEMS mirror 210 according to one or more embodiments. The MEMS mirror 210 is shown with four actuators 220. The reflective surface 215 of the MEMS mirror 210 is visible in the view shown in FIG. 2. The connection between the MEMS mirror 210 and the actuators 220 may be hinged to provide support while allowing movement of the MEMS mirror 210. Two axes x and y are indicated to show that the MEMS mirror 210 may tilt around the x axis and/or they axis. That is, the MEMS mirror 210 may have a non-zero tilt angle 211 around the x axis and may additionally or alternatively have a non-zero tilt angle 212 around they axis.

A controller 230 is shown to provide a signal 205 to each of the actuators 220 (i.e., MEMS). The signal 205 may be a current, for example, that is applied through a coil 320, as discussed with reference to FIG. 3. The controller 230 may be specific to the lidar system 110 and include processing circuitry as described for the controller 120. Additionally or alternately, the controller 120 may provide the signal 205 to the actuators 220 of the optical mirror assembly 200

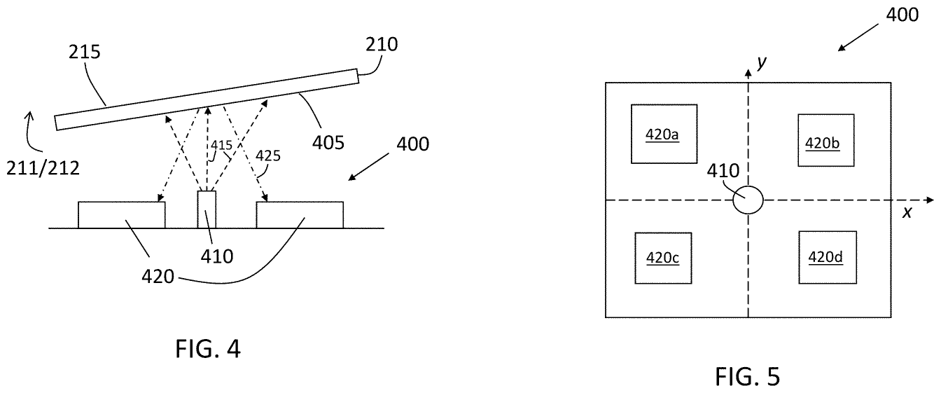

FIG. 3 is a cross-sectional view of relevant aspects of an exemplary optical mirror assembly 200 that includes a feedback sensor 400 to facilitate f closed-loop control of an orientation of the MEMS mirror 210 according to one or more embodiments. Two exemplary actuators 220 are shown, although the feedback sensor 400 is not affected by the particular actuation of the MEMS mirror 210. Each exemplary actuator 220 includes a base 300 with a cavity that holds a magnet 310 affected by current signal 205 passing through a coil 320. In the exemplary case, the signal 205 to each of the actuators 220 results in a tilt in the MEMS mirror 210, as shown. The feedback sensor 400 shown below the MEMS mirror 210 is further detailed with reference to FIGS. 4 and 5.

FIG. 4 is a side view of aspects of a feedback sensor 400 for the MEMS mirror 210 according to one or more embodiments. The MEMS mirror 210 is shown with the reflective surface 215 and the back surface 405, opposite the reflective surface 215, above the feedback sensor 400. The side view of the feedback sensor 400 shows an inverted LED 410 and two of the photodiodes 420. The inverted LED 410 emits light 415 at the back surface 405 of the MEMS mirror 210, and each of the photodiodes 420 receives reflected light 425 that results from the back surface 405 of the MEMS mirror 210 reflecting the emitted light 415. The intensity of reflected light 425 received by each photodiode 420 depends on the orientation of the MEMS mirror 210. Thus, the intensity of reflected light 425 that is received by each photodiode 420 facilitates determining the orientation of the MEMS mirror 210, as detailed with reference to FIG. 5.

FIG. 5 is a block diagram of a feedback sensor 400 for the MEMS mirror 210 according to one or more embodiments. The view of the feedback sensor 400 is a top-down view from the perspective of the MEMS mirror 210. The inverted LED 410 is in the center of the feedback sensor 400. The axes x and y matching the tilt axes of the MEMS mirror 210, as shown in FIG. 2, are indicated. According to one or more embodiments, the feedback sensor 400 includes four photodiodes 420a, 420b, 420c, 420d (generally referred to as 420) that are not on the tilt axes x and y of the MEMS mirror 210. For clarity, if the two photodiodes 420 shown in the side view of FIG. 4 were photodiodes 420a and 420c, then the MEMS mirror 210 in FIG. 4 exhibits a negative tilt angle 211 around the x axis. If, instead, the two photodiodes 420 shown in the side view of FIG. 4 were photodiodes 420c and 420d, then the MEMS mirror 210 in FIG. 4 exhibits a negative tilt angle 212 around they axis.

As previously noted, the use of the inverted LED 410 is one of the distinguishing features of the feedback sensor 400 according to one or more embodiments. The inverted LED 410 exhibits different angular intensity (i.e., a different illumination-to-MEMS mirror tilt angle characteristic) as compared with a conventional LED. Specifically, as the tilt angle of the MEMS mirror 210 (around either the x or y axes) goes from −20 degrees through 0 degrees to 20 degrees, the percentage of illumination from a conventional LED decreases while the percentage of illumination from an inverted LED 410 increases. The decrease for the conventional LED is less than the increase for the inverted LED 410. The resultant, which is a product of percentage illumination and photodiode reflectance, is non-linear for the conventional LED and approximately linear for the inverted LED 410. These differences lead to a lower signal-to-noise ratio (SNR) for the conventional LED as compared to the inverted LED 410.

According to prior feedback devices, a pair of light detectors are placed on each of the axes x and y. Thus, a tilt of the MEMS mirror 210 around the x axis would result in the MEMS mirror 210 being closer to one of the light detectors on the y axis than to the other light detector on they axis. Consequently, the two light detectors on they axis would receive different intensities of reflections. Similarly, a tilt of the MEMS mirror 210 around they axis would result in the two light detectors on the x axis receiving different intensities of reflections.

As previously noted, the four photodiodes 420a, 420b, 420c, 420d not being on the tilt axes x and y of the MEMS mirror 210 is another distinguishing feature of the feedback sensor 400 according to one or more embodiments. Each of the photodiodes 420 is disposed in a different quadrant defined by the x axis and the y axis. As a result of the off-axis arrangement, all four photodiodes 420 contribute to a determination of the tilt angle 211 of the MEMS mirror 210 around either the x and all four photodiodes 420 also contribute to the determination of the tilt angle 212 of the MEMS mirror 210 around they axis. When the analog detected intensity of the reflected light 425 at each photodiode 420 is digitized, the accuracy of the feedback sensor 400 according to one or more embodiments is improved through the use of four photodiodes 420 to determine tilt angles 211, 212 of the MEMS mirror 210 rather than two.

The controller 230, the controller 120, or a combination may be used to process the intensity of reflected light 425 detected by each photodiode 420 and perform closed-loop control of the orientation of the MEMS mirror 210. The intensity of the reflected light 425 received at each of the photodiodes 420a, 420b, 420c, and 420d is respectively designated as PDa, PDb, PDc, and PDd. To determine the tilt angle 211 of the MEMS mirror 210 around the x axis, a difference D1 is determined as:

D1=(PDc+PDd)−(PDa+PDb) [EQ. 1]

To determine the tilt angle 212 of the MEMS mirror 210 around they axis, a difference D2 is determined as:

D2=(PDb+PDd)−(PDa+PDc) [EQ. 2]

The difference D1 is mapped to a tilt angle 211 and the difference D2 is mapped to a tilt angle 212. This mapping, which is based on a prior calibration, represents the true orientation of the MEMS mirror 210, which may or may not match the desired orientation based on the signals 205 provided to the actuators 220.

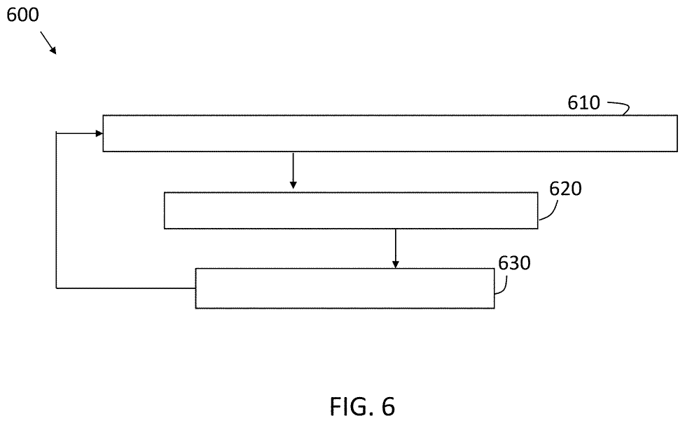

FIG. 6 is a process flow of a method 600 of performing closed-loop control of the orientation of a MEMS mirror 210 based on a feedback sensor 400 according to one or more embodiments. At block 610, providing a control signal 205 to affect the orientation of the MEMS mirror 210 refers to a controller 230 providing a control signal 205 (e.g., current) to each actuator 220 to affect tilt angle 211 and/or tilt angle 212 of the MEMS mirror 210. At block 620, obtaining feedback of the true orientation of the MEMS mirror 210 refers to using the feedback sensor 400 as detailed herein. Based on the true orientation of the MEMS mirror 210, as indicated by the feedback sensor 400, determining a correction, at block 630, refers to determining a difference between the true tilt angle 211 around the x axis and the desired tilt angle around the x axis and a difference between the true tilt angle 212 around they axis and the desired tilt angle around the y axis. These differences represent a correction needed in the orientation and are used to provide additional control signals 205 to the actuators 220 according to a closed-loop control scheme, as indicated in FIG. 6.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. An optical mirror assembly comprising:
a mirror with a reflective surface and a back surface, opposite the reflective surface, wherein the mirror is configured to be tilted around a first axis or a second axis, perpendicular to the first axis;
an inverted light emitting device (LED) of a feedback sensor arranged to emit light onto the back surface of the mirror; and
four photodiodes of the feedback sensor arranged to receive reflected light resulting from the back surface of the mirror reflecting the light emitted by the inverted LED, each of the four photodiodes being disposed in a different one of four quadrants defined by the first axis and the second axis and the inverted LED being disposed at a center of the four photodiodes.

2. The optical mirror assembly according to claim 1, further comprising actuators configured to tilt the mirror around the first axis or the second axis based on control signals provided to the actuators.

3. The optical mirror assembly according to claim 2, wherein each of the actuators is a micro-electro-mechanical system.

4. The optical mirror assembly according to claim 2, further comprising a controller configured to provide the control signals to the actuators to orient the mirror with a desired tilt angle around the first axis and a desired tilt angle around the second axis.

5. The optical mirror assembly according to claim 4, wherein the controller is configured to obtain an indication of intensity of the reflected light received by each of the four photodiodes.

6. The optical mirror assembly according to claim 5, wherein the controller is configured to determine actual orientation of the mirror including an actual tilt angle around the first axis and an actual tilt angle around the second axis based on the intensity of the reflected light received from the four photodiodes, the intensity of the reflected light received from all of the four photodiodes being used to determine both the actual tilt angle around the first axis and the actual tilt angle around the second axis.

7. The optical mirror assembly according to claim 6, wherein the controller is configured to determine a correction in orientation as a difference between the actual tilt angle and the desired tilt angle around the first axis and a difference between the actual tilt angle and the desired tilt angle around the second axis.

8. The optical mirror assembly according to claim 7, wherein the controller is configured to provide correction control signals to the actuators based on the correction in orientation to achieve the desired tilt angle around the first axis and the desired tilt angle around the second axis.

9. A method of assembling an optical mirror assembly, the method comprising:
disposing a mirror with a reflective surface and a back surface, opposite the reflective surface, wherein the mirror is configured to be tilted around a first axis or a second axis, perpendicular to the first axis;
arranging an inverted light emitting device (LED) of a feedback sensor to emit light onto the back surface of the mirror; and
arranging four photodiodes of the feedback sensor to receive reflected light resulting from the back surface of the mirror reflecting the light emitted by the inverted LED, each of the four photodiodes being disposed in a different one of four quadrants defined by the first axis and the second axis and the inverted LED being disposed in a center of the four photodiodes.

10. The method according to claim 9, further comprising arranging actuators to tilt the mirror around the first axis or the second axis based on control signals provided to the actuators.

11. The method according to claim 10, further comprising configuring a controller to provide the control signals to the actuators to orient the mirror with a desired tilt angle around the first axis and a desired tilt angle around the second axis.

12. The method according to claim 11, further comprising coupling the controller to the four photodiodes to obtain an indication of intensity of the reflected light received by each of the four photodiodes.

13. The method according to claim 12, further comprising configuring the controller to determine actual orientation of the mirror including an actual tilt angle around the first axis and an actual tilt angle around the second axis based on the intensity of the reflected light received from the four photodiodes, wherein the intensity of the reflected light received from all of the four photodiodes is used to determine both the actual tilt angle around the first axis and the actual tilt angle around the second axis.

14. The method according to claim 13, further comprising configuring the controller to determine a correction in orientation as a difference between the actual tilt angle and the desired tilt angle around the first axis and a difference between the actual tilt angle and the desired tilt angle around the second axis.

15. The method according to claim 14, further comprising configuring the controller to provide correction control signals to the actuators based on the correction in orientation to achieve the desired tilt angle around the first axis and the desired tilt angle around the second axis.

16. A method of performing closed-loop control of a mirror of an optical mirror assembly, the method comprising:
emitting light, using an inverted light emitting device (LED), onto a back surface of a mirror with a reflective surface opposite the back surface, wherein the mirror is configured to tilt around a first axis or a second axis that is perpendicular to the first axis; and
receiving reflected light, using four photodiodes respectively disposed in different ones of four quadrants defined by the first axis and the second axis, the reflected light resulting from the back surface of the mirror reflecting the light emitted by the inverted LED, the inverted LED being disposed in a center of the four photodiodes.

17. The method according to claim 16, further comprising providing, using a controller, control signals to micro-electro-mechanical actuators to tilt the mirror to a desired tilt angle around the first axis and a desired tilt angle around the second axis according to the control signals.

18. The method according to claim 17, further comprising the controller obtaining an indication of intensity of the reflected light received by each of the four photodiodes.

19. The method according to claim 18, further comprising the controller determining a true tilt angle around the first axis using the intensity of the reflected light received by all of the four photodiodes and determining a true tilt angle around the second axis using the intensity of the reflected light received by all of the four photodiodes.

20. The method according to claim 19, further comprising the controller providing additional control signals to the actuators based on a difference between the actual tilt angle and the desired tilt angle around the first axis and a difference between the actual tilt angle and the desired tilt angle around the second axis to obtain the desired tilt angle around the first axis and the desired tilt angle around the second axis for the mirror.
